(19) United States
(12) Patent Application Publication
(10) Pub. No.: US 2026/0180620 A1
(43) Pub. Date: Jun. 25, 2026

(54) INTERNAL REFLECTION TUNING AND OPTIMIZATION FOR FULL DUPLEX NODE AND AMPLIFIER

(71) Applicant: ARRIS Enterprises LLC, Horsham, PA (US)

(72) Inventors: Zhijian SUN, Monroe, WA (US); Brent D. ARNOLD, Doylestown, PA (US); Shamsuddin H. CHASMAWALA, Avon, CT (US); Marcel Franz Christian SCHEMMANN, Maria Hoop (NL)

(73) Assignee: ARRIS Enterprises LLC, Horsham, PA (US)

(21) Appl. No.: 19/104,635

(22) PCT Filed: Sep. 18, 2024
(86) PCT No.: PCT/US2024/047328

§ 371 Date: Feb. 18, 2025

Related U.S. Application Data
(60) Provisional application No. 63/539,048, filed on Sep. 18, 2023.
(60) Provisional application No. 63/604,695, filed on Nov. 30, 2023.
(60) Provisional application No. 63/632,906, filed on Apr. 11, 2024.

(51) Int. Cl. H04B 3/23; H03F 3/19

(52) U.S. Cl. CPC H04B 3/232; H03F 3/19; H03F 2200/318

(57) ABSTRACT

Devices, systems, and methods for an internal reflection cancelling full duplex node. The internal reflection cancelling full duplex node is a full duplex node with a coupler and a tunable coupler impedance matching network coupled to the coupler. The a coupler is coupled to a downstream line, an upstream line, and a common line. A power choke is coupled in parallel between the common line and ground. A common impedance matching network is interposed in the common line between the power choke and the output port.

### CROSS REFERENCE TO RELATED APPLICATIONS

The present application is a PCT International Patent application claiming the benefit of priority to U.S. Provisional Patent Application No. 63/539,048, filed Sep. 18, 2023, as well as U.S. Provisional Patent Application No. 63/632,906, filed Apr. 11, 2024, and U.S. Provisional Patent Application No. 63/604,695, filed Nov. 30, 2023, the contents of which are each incorporated herein by reference in their entirety.

### BACKGROUND

The subject matter of this application relates to amplifiers in full duplex communications architectures.

Cable Television (CATV) services typically provide content to large groups of subscribers from a central delivery unit, called a “head end,” which distributes channels of content to its subscribers from this central unit through a branch network comprising a multitude of intermediate nodes. Modern Cable Television (CATV) service networks, however, not only provide media content such as television channels and music channels to a customer, but also provide a host of digital communication services such as Internet Service, Video-on-Demand, telephone service such as VoIP, and so forth. These digital communication services, in turn, require not only communication in a downstream direction from the head end, through the intermediate nodes and to a subscriber, but also require communication in an upstream direction from a subscriber and to the content provider through the branch network.

To this end, CATV head ends have historically included a separate Cable Modem Termination System (CMTS), used to provide high speed data services, such as video, cable Internet, Voice over Internet Protocol, etc. to cable subscribers. Typically, a CMTS will include both Ethernet interfaces (or other more traditional high-speed data interfaces) as well as RF interfaces so that traffic coming from the Internet can be routed (or bridged) through the Ethernet interface, through the CMTS, and then into the optical RF interfaces that are connected to the cable company's hybrid fiber coax (HFC) system. Downstream traffic is delivered from the CMTS to a cable modem in a subscriber's home, while upstream traffic is delivered from a cable modem in a subscriber's home back to the CMTS. Many modern CATV systems have combined the functionality of the CMTS with the video delivery system (EdgeQAM) in a single platform called the Converged Cable Access Platform (CCAP). Still other modern CATV systems called Remote PHY (or R-PHY) relocate the physical layer (PHY) of a traditional CCAP by pushing it to the network's fiber nodes. Thus, while the core in the CCAP performs the higher layer processing, the R-PHY device in the node converts the downstream data sent by the core to be transmitted on radio frequency from digital to analog and converts the upstream RF data sent by cable modems to be transmitted optically to the core from analog-to-digital format.

Regardless of which architectures were employed, historical implementations of CATV systems bifurcated available bandwidth into upstream and downstream transmissions, i.e., data was only transmitted in one direction across any part of the spectrum. For example, early iterations of the Data Over Cable Service Interface Specification (DOCSIS) assigned upstream transmissions to a frequency spectrum between 5 MHz and 42 MHz and assigned downstream transmissions to a frequency spectrum between 50 MHz and 750 MHz. Though later iterations of the DOCSIS standard expanded the width of the spectrum reserved for each of the upstream and downstream transmission paths, the spectrum assigned to each respective direction did not overlap.

Full Duplex DOCSIS (FDX) is a DOCSIS 4.0 technology that enables higher data bandwidth for consumers. This technology shares the same frequency band (108-684 MHz, for example) for downstream and upstream signals to support higher bandwidth. With FDX DOCSIS, upstream and downstream spectrum is no longer separated, allowing up to 5 Gbps upstream service and 10 Gbps downstream service over the cable access network. In a full duplex system, because the CCAP/R-PHY core knows the characteristics of its own downstream transmission, it can distinguish upstream communications transmitted in the same frequencies that it provides those downstream services. Cable modems receive data on the downstream and then transmit data on the upstream as scheduled by the Cable Modem Termination System (CMTS), but no cable modem will transmit and receive at the same time as other cable modems on the same cable.

In previous versions of DOCSIS a cable modem was limited in the downstream with only one or two OFDM (Orthogonal Frequency Division Multiplexing) channels and in the upstream by having at best two OFDMA (Orthogonal Frequency Division Multiple Access) channels. While the modem could receive downstream and transmit upstream simultaneously, the upstream channels were shared with many other modems. The number of cable modems served by a node for FDX DOCSIS will almost always be smaller because there must not be active devices (i.e., amplifiers) after the node. With FDX DOCSIS, the modem has a minimum of four downstream OFDM channels and seven upstream OFDMA channels. The net result is much more bandwidth in the upstream and downstream to each modem. The time to switch between upstream and downstream transmitting is extremely short and managed by the CMTS, resulting in very high speeds for a particular cable modem.

Due to use of the same frequency band for downstream and upstream signals in FDX DOCSIS, a complex signal processing unit is required to process received FDX signals to cancel out the reflections or echoes. These echoes need to be cancelled in order to achieve the desired performance level. The total amount of echo cancellation (EC) by signal processing is limited. Minimizing reflections as much as possible is desired in order to maintain as much of the total echo cancellation budget for a system as possible.

FIG. 1 shows a typical output stage of a legacy full duplex node 1. The legacy full duplex node 1 configured for transmitting a downstream signal and for receiving an upstream signal.

The legacy full duplex node 1 has a launch amplifier 40, a coupler 2, a power choke 10, a common impedance matching network 20, and an output port (seizure mechanism) 21. The launch amplifier 40 is configured to receive a downstream signal 24 from a downstream transmitter (not shown), amplify the downstream signal 24, and transmit it out. The launch amplifier 40 is interposed in a downstream line between a first segment 11 of the downstream line coupled to an input of the launch amplifier 40 and a second segment 12 of the downstream line coupled to an output of the launch amplifier 40. The coupler 2 is coupled to the second segment downstream line 12 and is coupled to a first segment 15 of a common line. The power choke 10 is coupled in parallel between the common line and ground, interposed in the common line between the first segment 15 of the common line and a second segment 16 of the common line. The power choke 10 has a parasitic capacitance 48 modelled as a discrete capacitance interposed in the first segment 15 of the common line upstream of the power choke 10. The common impedance matching network 20 is interposed in the common line between the second segment 16 of the common line and a third segment 17 of the common line. The output port (seizure mechanism) 21 is coupled to the third segment 17 of the common line. The output port (seizure mechanism) 21 is designed to impedance match with the external cable network (not shown) and the rest of the legacy full duplex node 1 as much as practicable but does not do so ideally.

The common impedance matching network 20 typically comprises a first capacitor 44, an inductor 42, and a second capacitor 46. The first capacitor 44 is coupled between a first end of the inductor 42 and ground. The second capacitor 46 is coupled between a second end of the inductor 42 and ground. The inductor 42, the first capacitor 44 and the second capacitor 46 are typically variable to allow for fine tuned impedance matching.

The coupler 2 has a coupler input port 3, a coupler common port 4, a coupler output port 5, and a coupler isolation port 6. The coupler 2 is a bi-directional type and is a cross-connected transformer. The coupler 2 is configured to receive a downstream signal 24 into the coupler input port 3, transmit a first portion of the downstream signal 24 out of the coupler common port 4, transmit a second portion of the downstream signal 24 out of the coupler isolation port 6, and transmit a third portion of the downstream signal 24 out of the coupler output port 5, wherein the first portion is greater than the second portion and the second portion is greater than the third portion. The coupler 2 is further configured to receive an upstream signal 26 into the coupler common port 4, transmit a first portion of the upstream signal 26 out of the coupler input port 3, transmit a second portion of the upstream signal 26 out of the coupler output port 5, and transmit a third portion of the upstream signal 26 out of the coupler isolation port 6, wherein the first portion is greater than the second portion and the second portion is greater than the third portion.

The coupler input port 3 is coupled to the second segment downstream line 12 and the coupler common port 4 is coupled to the first segment 15 of the common line. A first load 8 is coupled between the coupler isolation port 6 and ground. An upstream line 14 is coupled to the coupler output port 5. The upstream line 14 is configured to be coupled to an upstream receiver (not shown).

In operation, a downstream signal 24 passes through the launch amplifier 40 to the coupler input port 3 of the coupler 2. The downstream signal 24 passes out of the coupler common port 4, diminished somewhat in strength as a portion is coupled to the coupler isolation port 6. The isolation between the coupler isolation port 6 and the coupler output port 5 is not perfect, so a portion of the downstream signal 24 leaks through to coupler output port 5 as coupler isolation leakage 34. The downstream signal 24 then passes through the first segment common line 15, the second segment common line 16, the common impedance matching network 20 and the third segment common line 17 before encountering the output port (seizure mechanism) 21. When the downstream signal 24 hits the output port (seizure mechanism) 21, a portion of the downstream signal 24 may be reflected back as a first internal reflection 30, the strength of the reflection depending on the impedance matching between the output port (seizure mechanism) 21 and the rest of the legacy full duplex node 1. The power choke 10 may also cause a second internal reflection 32 back into the first segment common line 15. A combined internal reflection 36 comprising the first internal reflection 30, the second internal reflection 32, and the coupler isolation leakage 34 will pass into the upstream line 14. An upstream signal 26 cannot be effectively received by the upstream signal receiver (not shown) coupled to the upstream line 14 unless the strength of the combined internal reflection 36 is below a level that can be handled by signal processing echo cancellation in the upstream signal receiver.

When an upstream signal 26 hits the output port (seizure mechanism) 21 from the external cable network, a portion may be reflected back as an external reflection 28, the strength of the reflection depending on the impedance matching between the output port (seizure mechanism) 21 and the external cable network. The main undesirable effect of external reflections on the legacy full duplex node 1 is the loss of signal strength (external return loss) of the upstream signal 26, but it will also likely have undesirable effects on the receivers in the cable modems (not shown) on the external cable network.

The exemplary legacy full duplex node 1 is typically tuned to minimize external return loss by adjusting the variable components in the common impedance matching network 20. It is also desirable to reduce the internal return loss (internal reflections) and the same common impedance matching network 20 can used to achieve this reduction. However, in most cases, the common impedance matching network 20 can only tune either to obtain optimal external return loss or optimal internal return loss, but not both.

FIG. 2 shows the coupler 2 from FIG. 1 with coupler isolation port 6 and coupler common port 4 each terminated with a perfect 75 ohm load (first load 8 and second load 52 respectively). With ideal components, this results in perfect impedance matching and no internal or external reflections. However, in a real system, such as the legacy full duplex node 1 in FIG. 1, the coupler common port 4 will be loaded with 0.5-0.7 pF parasitic capacitance from the power choke parasitic capacitance 48. The impedance matching between the output port (seizure mechanism) 21 and the external cable network is not ideal. The impedance mismatching between the coupler isolation port 6 and the coupler common port 4 is also not ideal, which causes the isolation of the coupler 2 to be less than optimal.

What is needed is a way other than signal processing to cancel reflections internal to an FDX node.

### BRIEF DESCRIPTION OF THE DRAWINGS

For a better understanding of the invention, and to show how the same may be carried into effect, reference will now be made, by way of example, to the accompanying drawings, in which:

FIG. 1 shows a legacy full duplex node.

FIG. 2 shows the coupler from FIG. 1 with isolation port and common port each terminated with a perfect 75 ohm load.

FIG. 3 shows a first exemplary embodiment of an internal reflection tuning full duplex node 100.

FIG. 4 shows a second exemplary embodiment of an internal reflection tuning full duplex node 200.

FIG. 5 shows a block diagram for an FDX amplifier.

FIG. 6 shows an exemplary output stage of the FDX amplifier of FIG. 5.

FIG. 7 shows an output stage of a single port FDX amplifier having adjustable impedance elements at the isolation port of the amplifier's coupler.

FIG. 8 shows an output stage of a dual port FDX amplifier having adjustable impedance elements at the isolation port of the amplifier's couplers.

### DETAILED DESCRIPTION

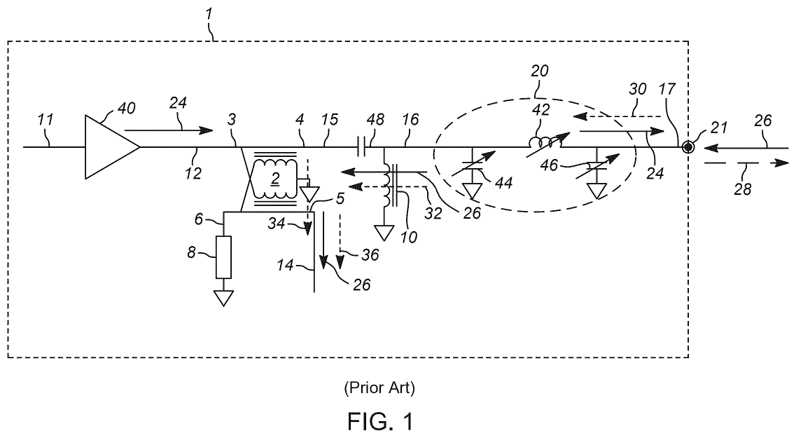

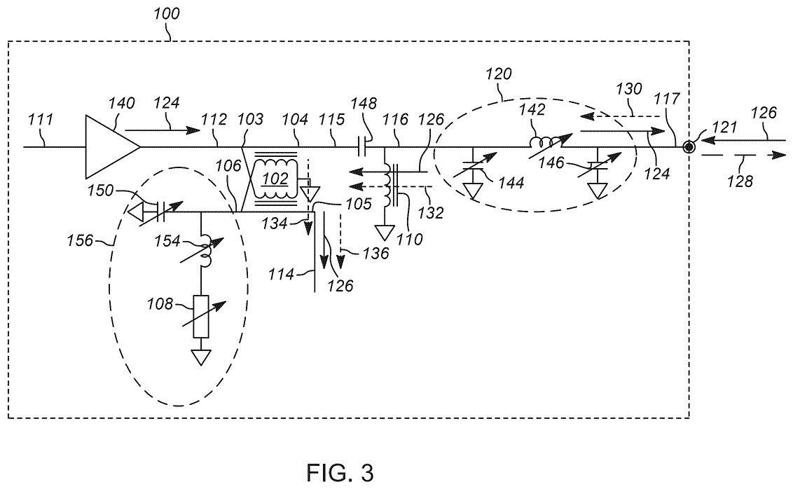

FIG. 3 shows a first exemplary embodiment of an internal reflection tuning full duplex node 100. The first embodiment internal reflection tuning full duplex node 100 is similar to the legacy full duplex node 1 shown in FIG. 1, but instead of using a 75 ohm load at the coupler isolation port 6 of the coupler 2, a tunable coupler impedance matching network is used.

The first embodiment internal reflection tuning full duplex node 100 has a launch amplifier 140, a coupler 102, a power choke 110, a common impedance matching network 120, an output port (seizure mechanism) 121, and a tunable coupler impedance matching network 156. The launch amplifier 140 is configured to receive a downstream signal 124 from a downstream transmitter (not shown), amplify the downstream signal 124, and transmit it out. The launch amplifier 140 is interposed in a downstream line between a first segment 111 of the downstream line coupled to an input of the launch amplifier 140 and a second segment 112 of the downstream line coupled to an output of the launch amplifier 140. The coupler 102 is coupled to the second segment downstream line 112 and is coupled to a first segment 115 of a common line. The power choke 110 is coupled in parallel between the common line and ground, interposed in the common line between the first segment 115 of the common line and a second segment 116 of the common line. The power choke 110 has a parasitic capacitance 148 modelled as a discrete capacitance interposed in the first segment 115 of the common line upstream of the power choke 110. The common impedance matching network 120 is interposed in the common line between the second segment 116 of the common line and a third segment 117 of the common line. The output port (seizure mechanism) 121 is coupled to the third segment 117 of the common line. The output port (seizure mechanism) 121 is configured to couple with an external cable network (not shown). The output port (seizure mechanism) 121 is designed to impedance match with the external cable network and with the rest of the first embodiment internal reflection tuning full duplex node 100 as much as practicable but does not do so ideally.

The common impedance matching network 120 comprises a first capacitor 144, a first inductor 142, and a second capacitor 146. The first capacitor 144 is coupled between a first end of the first inductor 142 and ground. The second capacitor 146 is coupled between a second end of the first inductor 142 and ground. The first inductor 142, the first capacitor 144 and the second capacitor 146 are variable to allow for fine tuned impedance matching.

The coupler 102 has a coupler input port 103, a coupler common port 104, a coupler output port 105, and a coupler isolation port 106. The coupler 102 is a bi-directional type and is a cross-connected transformer. The coupler 102 is configured to receive a downstream signal 124 into the coupler input port 103, transmit a first portion of the downstream signal 124 out of the coupler common port 104, transmit a second portion of the downstream signal 124 out of the coupler isolation port 106, and transmit a third portion of the downstream signal 124 out of the coupler output port 105, wherein the first portion is greater than the second portion and the second portion is greater than the third portion. The coupler 102 is further configured to receive an upstream signal 126 into the coupler common port 104, transmit a first portion of the upstream signal 126 out of the coupler input port 103, transmit a second portion of the upstream signal 126 out of the coupler output port 105, and transmit a third portion of the upstream signal 126 out of the coupler isolation port 106, wherein the first portion is greater than the second portion and the second portion is greater than the third portion.

The coupler input port 103 is coupled to the second segment downstream line 112 and the coupler common port 104 is coupled to the first segment 115 of the common line. An upstream line 114 is coupled to the coupler output port 105. The upstream line 114 is configured to be coupled to an upstream receiver (not shown). The tunable coupler impedance matching network 156 is coupled between the coupler isolation port 106 and ground.

The tunable coupler impedance matching network 156 comprises a fourth capacitor 150, a second inductor 154, and a resistive load 108. The fourth capacitor 150 is coupled between the coupler isolation port 106 and ground. The second inductor 154 and the resistive load 108 are coupled parallel to the fourth capacitor 150 between coupler isolation port 106 and ground. The fourth capacitor 150, the second inductor 154, and the resistive load 108 are variable to allow for tuning of the tunable coupler impedance matching network 156.

To prepare for operations, the first embodiment internal reflection tuning full duplex node 100 is tuned to minimize external return loss by adjusting the variable components in the common impedance matching network 120. Then the tunable coupler impedance matching network 156 is tuned so that internal reflection is minimized. This internal reflection tuning process has no impact on external return loss.

In operation, a downstream signal 124 passes through the launch amplifier 140 to the input port 103 of the coupler 102. The downstream signal 124 passes out of the coupler common port 104, diminished somewhat in strength as a portion is coupled to the coupler isolation port 106. The isolation between the coupler isolation port 106 and the coupler output port 105 is not perfect, so a portion of the downstream signal 124 leaks through to coupler output port 105 as coupler isolation leakage 134. The downstream signal 124 then passes through the first segment common line 115, the second segment common line 116, the common impedance matching network 120 and the third segment common line 117 before encountering the output port (seizure mechanism) 121. When the downstream signal 124 hits the output port (seizure mechanism) 121, a portion of the downstream signal 124 may be reflected back as a first internal reflection 130, the strength of the reflection depending on the impedance matching between the output port (seizure mechanism) 121 and the rest of the first embodiment internal reflection tuning full duplex node 100. The power choke 110 may also cause a second internal reflection 132 back into the first segment common line 115 and the coupler 102. A combined internal reflection 136 comprising the first internal reflection 130, the second internal reflection 132, and the coupler isolation leakage 134 will pass into the upstream line 114. An upstream signal 126 cannot be effectively received by the upstream signal receiver (not shown) coupled to the upstream line 114 unless the strength of the combined internal reflection 136 is below a level that can be handled by signal processing echo cancellation in the upstream signal receiver. The tunable coupler impedance matching network 156 when tuned minimizes the first internal reflection 130, the second internal reflection 132, and the coupler isolation leakage 134.

When an upstream signal 126 hits the output port (seizure mechanism) 121 from the external cable network, a portion may be reflected back as an external reflection 128, the strength of the reflection depending on the impedance matching between the output port (seizure mechanism) 121 and the external cable network. The main undesirable effect of external reflections on the first embodiment internal reflection tuning full duplex node 100 is the loss of signal strength (external return loss) of the upstream signal 126, but it will also likely have undesirable effects on the receivers in the cable modems (not shown) on the external cable network.

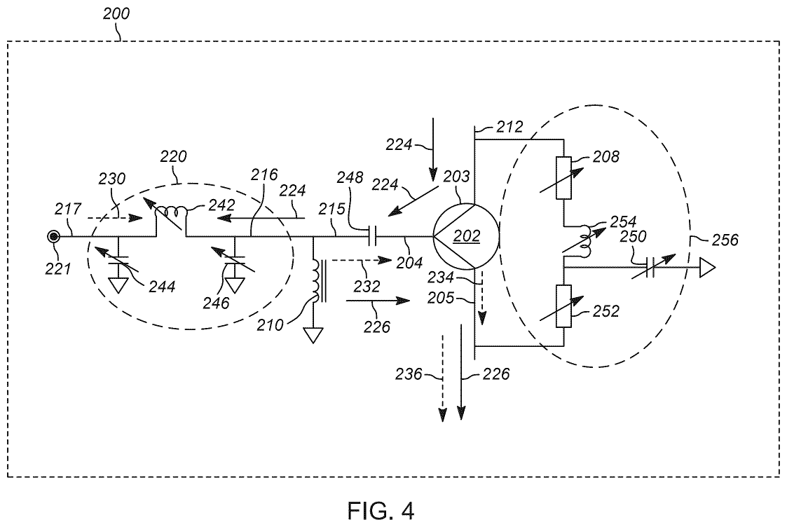

FIG. 4 shows a second exemplary embodiment of an internal reflection tuning full duplex node 200. The second embodiment internal reflection tuning full duplex node 200 is similar to the first embodiment internal reflection tuning full duplex node 100 shown in FIG. 3 but uses a splitter instead of the coupler 102. Instead of the tunable coupler impedance matching network 156, a s tunable splitter impedance matching network is used with topology that is different from the tunable coupler impedance matching network 156.

The second embodiment internal reflection tuning full duplex node 200 has a splitter 202, a power choke 210, a common impedance matching network 220, an output port (seizure mechanism) 221, and a tunable splitter impedance matching network 256. The splitter 202 is coupled to a downstream line 212 and is coupled to a first segment common line 215. The power choke 210 is coupled in parallel between the common line and ground, interposed in the common line between the first segment common line 215 of the common line and a second segment common line 216 of the common line. The power choke 210 has a parasitic capacitance 248 modelled as a discrete capacitance interposed in the first segment 215 of the common line upstream of the power choke 210. The common impedance matching network 220 is interposed in the common line between the second segment 216 of the common line and a third segment 217 of the common line. The output port (seizure mechanism) 221 is coupled to the third segment 217 of the common line. The output port (seizure mechanism) 221 is configured to couple with an external cable network (not shown). The output port (seizure mechanism) 221 is designed to impedance match with the external cable network and with the rest of the second embodiment internal reflection tuning full duplex node 200 as much as practicable but does not do so ideally.

The common impedance matching network 220 comprises a first capacitor 244, a first inductor 242, and a second capacitor 246. The first capacitor 244 is coupled between a first end of the first inductor 242 and ground. The second capacitor 246 is coupled between a second end of the first inductor 242 and ground. The first inductor 242, the first capacitor 244 and the second capacitor 246 are variable to allow for fine tuned impedance matching.

The splitter 202 has a splitter input port 203, a splitter common port 204, and a splitter output port 205. The splitter 202 is configured to receive a downstream signal 224 into the splitter input port 203, transmit a first portion of the downstream signal 224 out of the splitter common port 204, and transmit a second portion of the downstream signal 224 out of the splitter output port 205, wherein the first portion is greater than the second portion. The splitter 202 is further configured to receive an upstream signal 226 into the splitter common port 204, transmit a first portion of the upstream signal 226 out of the splitter output port 205 and transmit a second portion of the upstream signal 226 out of the splitter input port 203, wherein the first portion is greater than the second portion.

The splitter input port 203 is coupled to the downstream line 212, the splitter common port 204 is coupled to the first segment 215 of the common line, and the splitter output port 205 is coupled to the upstream line 214. The upstream line 214 is configured to be coupled to an upstream receiver (not shown). A tunable splitter impedance matching network 256 is coupled between the downstream line 212, the upstream line 214, and ground.

The tunable splitter impedance matching network 256 comprises a fourth capacitor 250, a second inductor 254, a first resistive load 208 and a second resistive load 252. The first resistive load 208, the second inductor 254 and the second resistive load 252 are coupled in series between the downstream line 212 and upstream line 214. A first end of the fourth capacitor 250 is coupled between the second inductor 254 and the second resistive load 252 and a second end of the fourth capacitor 250 is coupled to ground. The fourth capacitor 250, the second inductor 254, the first resistive load 208, and the second resistive load 252 are variable to allow for tuning of the tunable splitter impedance matching network 256.

To prepare for operations, the second embodiment internal reflection tuning full duplex node 200 is tuned to minimize external return loss by adjusting the variable components in the common impedance matching network 220. Then the tunable splitter impedance matching network 256 is tuned so that internal reflection is minimized. This internal reflection tuning process has no impact to regular external return loss.

In operation, a downstream signal 224 passes into the splitter input port 203 of the splitter 202. The downstream signal 224 passes out of the splitter common port 204, diminished somewhat in strength as a portion is coupled to the splitter output port 205. The isolation between the splitter common port 204 and the splitter output port 205 is not perfect, so a portion of the downstream signal 224 leaks through to splitter output port 205 as splitter isolation leakage 234. The downstream signal 224 then passes through the first segment 215 and second segment 216 of the common line, the common impedance matching network 220 and the third segment 217 of the common line before encountering the output port (seizure mechanism) 221. When the downstream signal 224 hits the output port (seizure mechanism) 221, a portion of the downstream signal 224 may be reflected back as a first internal reflection 230, the strength of the reflection depending on the impedance matching between the output port (seizure mechanism) 221 and the rest of the second embodiment internal reflection tuning full duplex node 200. The power choke 210 may also cause a second internal reflection 232 back into the first segment common line 215. A combined internal reflection 236 comprising the first internal reflection 230, the second internal reflection 232, and the splitter isolation leakage 234 will pass into the upstream line 214. An upstream signal 226 cannot be effectively received by the upstream signal receiver (not shown) coupled to the upstream line 214 unless the strength of the combined internal reflection 236 is below a level that can be handled by signal processing echo cancellation in the upstream signal receiver. The tunable splitter impedance matching network 256 when tuned minimizes the first internal reflection 230, the second internal reflection 232, and the splitter isolation leakage 234.

When an upstream signal 226 hits the output port (seizure mechanism) 221 from the external cable network, a portion may be reflected back as an external reflection, the strength of the reflection depending on the impedance matching between the output port (seizure mechanism) 221 and the external cable network. The main undesirable effect of external reflections on the second embodiment internal reflection tuning full duplex node 200 is the loss of signal strength (external return loss) of the upstream signal 226, but it will also likely have undesirable effects on the receivers in the cable modems (not shown) on the external cable network.

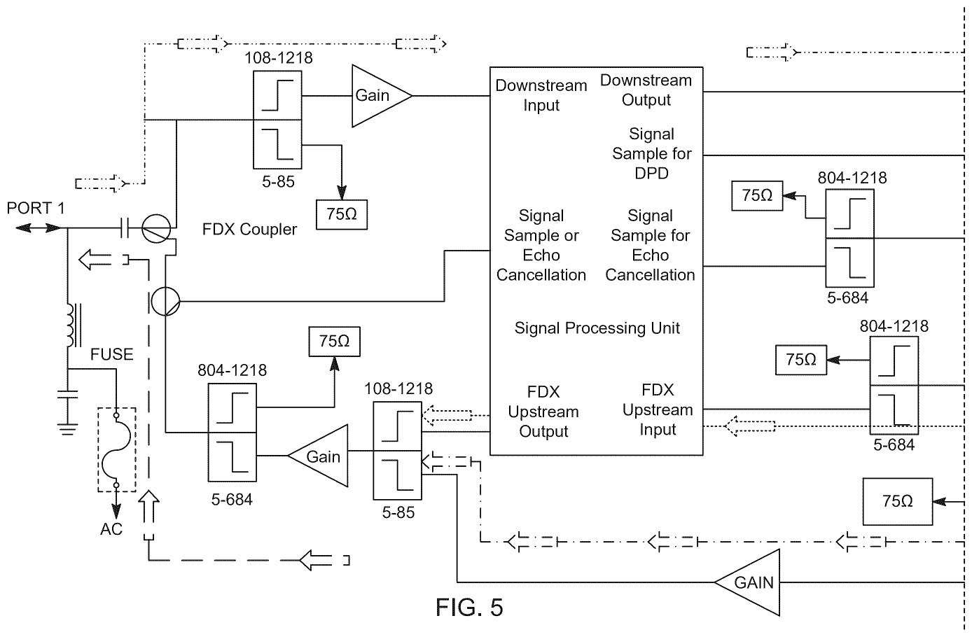

Full Duplex DOCSIS (FDX) is a DOCSIS 4.0 technology that enables higher data bandwidth for consumers. This technology shares the same frequency band (108-684 MHz, for example) for Downstream (DS) and Upstream (US) signals to support higher bandwidth. FIG. 5 shows a block diagram of a typical FDX amplifier. Due to simultaneous use of the same frequency band for Downstream and Upstream signals, a complex signal processing unit is required to process the FDX signals to cancel out the reflections or echoes travelling in undesired directions. These reflections need to be canceled in order to achieve the desired performance, however the total amount of echo cancellation (EC) is limited for a given technology. Since the reflections can be internal (from an FDX node or amplifier), or external (from the cable plant), minimizing the total reflections as much as possible is desired in order to maintain as much of the total EC budget for a system.

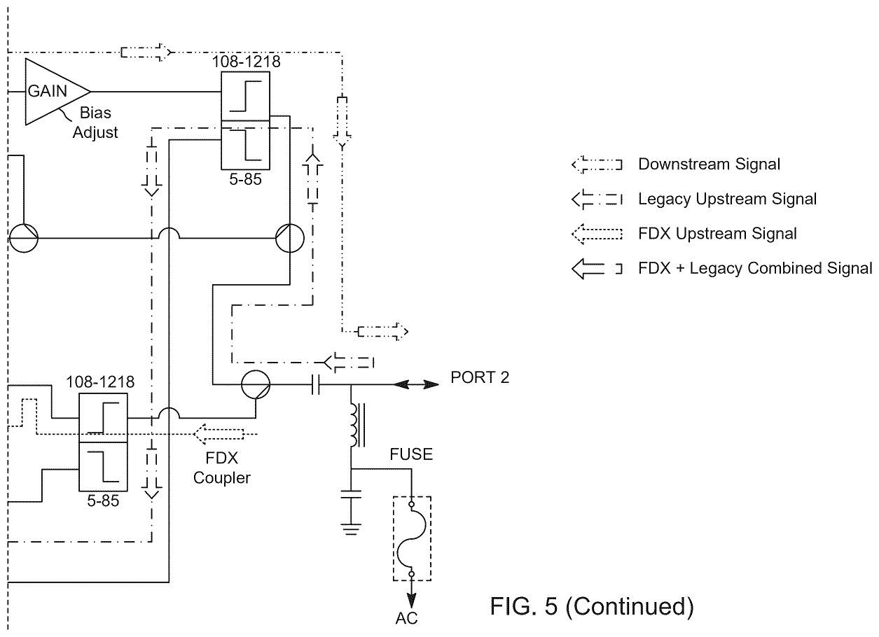

FIG. 6 shows a typical output stage 300 of a FDX node or amplifier and includes a downstream power amplifier 302, an FDX coupler 304, a power choke 306, one or more impedance matching networks 308, and a seizure mechanism 310. When the downstream signal reaches the seizure mechanism, some signals will be reflected back into the upstream path of the amplifier, which is the internal reflection. When the downstream signal exits the amplifier and enters the cable plant, these signals will also be reflected back into the upstream path from various elements in the cable plant, which are the external reflection(s). Internal and external reflections will add to, or subtract from each other based on magnitude and phase relationship of the signals.

This specification previously described a circuit that minimized the internal reflection with a perfect 75 ohm termination on the amplifier port. However, for deployments in the cable plant, the load at the amplifier port will not always be a perfect 75 ohm, therefore the internal refection may not be optimum in a field load condition. The external reflections created by network elements that are physically located close to the output port of a FDX amp or node can also add in-phase with the internal reflection, which might significantly reduce MER performance of FDX upstream signals. Therefore, the present specification also discloses a scheme to dynamically adjust the phase and magnitude of the internal reflection so that it will add out-of-phase with the near external reflection in a FDX node or amplifier design.

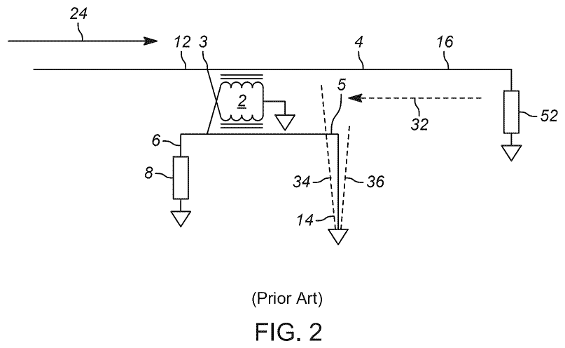

For a standalone prior art FDX coupler, such as that shown in FIG. 2, when both the isolation port and the common port are terminated with a perfect 75 ohm load, the isolation between main port and the coupling port is optimum (35-40 dB range). However, in a real system, such as that shown in FIG. 6, the common port of the FDX coupler will be loaded with a 0.5-0.7 pF parasitic capacitance from the power choke. The seizure mechanism impedance matching is also not ideal, and the impedance mismatch between the isolation port and the common port causes degradation of the FDX coupler's isolation.

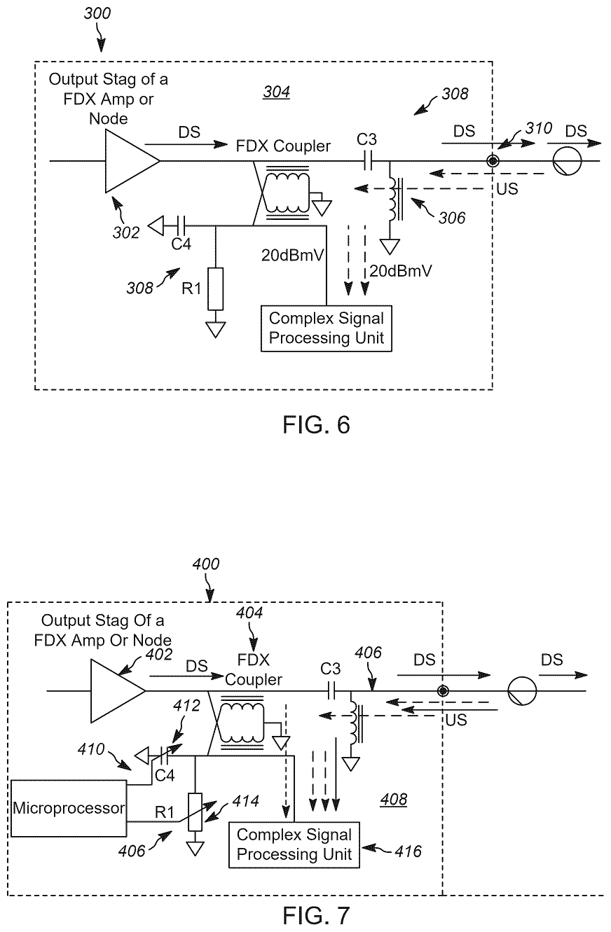

In contrast, instead of using a 75 ohm load at the isolation port of a FDX coupler, the present specification discloses the use of a tunable impedance matching network at the isolation port. Referring specifically to FIG. 7, an output stage 400 of an FDX amplifier may comprise a power amplifier 402 amplifying a downstream signal and providing it to an input port of an FDX coupler 404. An impedance matching network 406 comprising one or more resistors/capacitors/inductors, as well as a power choke, may be connected to the output of the FDX coupler 406. However, instead of an isolation port (such as 106 of FIG. 3) which terminates in a 75 ohm load, the circuit 400 includes an isolation port with adjustable impedance network 410. For example, an electrical variable capacitor 412 or varactor can be used for instead of a fixed-value capacitor and a digital potentiometer 414 or a pin diode can be used instead of a fixed-value. These adjustable elements can be controlled through a signal processor unit (microprocessor) 416.

The FDX upstream signal, together with downstream echo signals will be first digitized inside the signal processor unit 416. This signal processor unit 416 may be a Field Programmable Gate Array (FPGA) or an Application-specific Integrated Circuit (ASIC). When the signal processor unit 416 initially powers up, it may generate downstream signals and establish the Echo Cancellation (EC) engine. Once the EC engine is running, the signal processor unit 416 may monitor near reflections (both internal reflections and external reflections) and adjust the adjustable elements 412 and 414 to minimize the near reflection. By adjusting the impedance at the isolation port of the FDX coupler 400, the phase and amplitude of the internal reflection are adjusted, and when the internal reflection is out-of-phase with near external reflection, the total near reflection will be minimized.

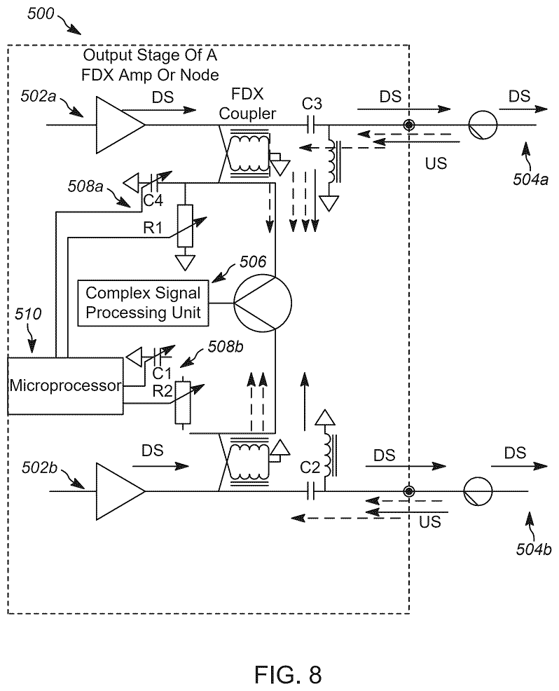

While FIG. 7 shows an output stage of one-port FDX amplifier, FIG. 8 illustrates an output stage 500 of an FDX amplifier having two input ports 502a and 502b, as well as two output ports 504a and 504b. Thus, the output stage 500 includes a FIG. 8 shows a signal processor unit (microprocessor) 510 that adjusts the respective values of one or more impedance elements in isolation port 508a for output 504a, and in isolation port 508b for output 504b.

During normal operation, FDX upstream signals have a scheduled quiet period and during this quiet period, the signal processor units 416, 510 may monitor the near reflection and adjust the impedance at the FDX coupler isolation port so that the near reflection is minimized, then may start the periodical EC training again.

The internal reflection is typically varied over temperature by +/−3 dB. This temperature variation will be minimized or eliminated by the signal processor units 416, 510, which periodically control the near reflection.

It will be appreciated that the invention is not restricted to the particular embodiments that have been described, and that variations may be made therein without departing from the scope of the invention as defined in the appended claims, as interpreted in accordance with principles of prevailing law, including the doctrine of equivalents or any other principle that enlarges the enforceable scope of a claim beyond its literal scope. Unless the context indicates otherwise, a reference in a claim to the number of instances of an element, be it a reference to one instance or more than one instance, requires at least the stated number of instances of the element but is not intended to exclude from the scope of the claim a structure or method having more instances of that element than stated. The word “comprise” or a derivative thereof, when used in a claim, is used in a nonexclusive sense that is not intended to exclude the presence of other elements or steps in a claimed structure or method.

1. An internal reflection cancelling full duplex node comprising:
an output port 121;
a coupler 102 coupled to a downstream line, an upstream line, and a common line;
a power choke 110 coupled in parallel between the common line and ground;
a common impedance matching network 120 interposed in the common line between the power choke 110 and the output port 121; and
a tunable coupler impedance matching network 156 coupled to the coupler 102; wherein the coupler 102 has a coupler input port 103 coupled to the downstream line, a coupler common port 104 coupled to the common line, a coupler output port 105 coupled to the upstream line, and a coupler isolation port 106 coupled to the tunable coupler impedance matching network 156.

2. (canceled)

3. The internal reflection cancelling full duplex node of claim 1,
wherein the tunable coupler impedance matching network 156 comprises a fourth capacitor 150, a second inductor 154, and a resistive load 108;
wherein the fourth capacitor 150 is coupled between the coupler isolation port 106 and ground;
wherein the second inductor 154 and the resistive load 108 are coupled parallel to the fourth capacitor 150 between the coupler isolation port 106 and ground;
wherein the fourth capacitor 150, the second inductor 154, and the resistive load 108 are variable.

4. The internal reflection cancelling full duplex node of claim 3,
wherein the coupler 102 is configured to receive a downstream signal 124 into the coupler input port 103, transmit a first portion of the downstream signal 124 out of the coupler common port 104, transmit a second portion of the downstream signal 124 out of the coupler isolation port 106, and transmit a third portion of the downstream signal 124 out of the coupler output port 105, wherein the first portion is greater than the second portion and the second portion is greater than the third portion; and
wherein the coupler 102 is further configured to receive an upstream signal 126 into the coupler common port 104, transmit a first portion of the upstream signal 126 out of the coupler input port 103, transmit a second portion of the upstream signal 126 out of the coupler output port 105, and transmit a third portion of the upstream signal 126 out of the coupler isolation port 106, wherein the first portion is greater than the second portion and the second portion is greater than the third portion.

5. The internal reflection cancelling full duplex node of claim 4,
wherein the common impedance matching network 120 comprises a first capacitor 144, a first inductor 142, and a second capacitor 146;
wherein the first capacitor 144 is coupled between a first end of the first inductor 142 and ground;
wherein the second capacitor 146 is coupled between a second end of the first inductor 142 and ground; and
wherein the first inductor 142, the first capacitor 144 and the second capacitor 146 are variable.

6. (canceled)

7. An internal reflection cancelling full duplex node comprising:
an output port 221;
a splitter 202 coupled to a downstream line, an upstream line, and a common line;
a power choke 210 coupled in parallel between the common line and ground;
a common impedance matching network 220 interposed in the common line between the power choke 210 and the output port 221; and
a tunable splitter impedance matching network 256 coupled to the splitter 202; wherein
the splitter 202 has a splitter input port 203 coupled to the downstream line, a splitter common port 204 coupled to the common line, and a splitter output port 205 coupled to the upstream line; and wherein
the tunable splitter impedance matching network 256 is coupled between the splitter input port 203 and the splitter output port 205.

8. (canceled)

9. The internal reflection cancelling full duplex node of claim 7,
wherein the tunable splitter impedance matching network 256 comprises a fourth capacitor 250, a second inductor 254, a first resistive load 208 and a second resistive load 252;
wherein the first resistive load 208, the second inductor 254 and the second resistive load 252 are coupled in series between the downstream line 212 and the upstream line 214;
wherein a first end of the fourth capacitor 250 is coupled between the second inductor 254 and the second resistive load 252 and a second end of the fourth capacitor 250 is coupled to ground; and
wherein the fourth capacitor 250, the second inductor 254, the first resistive load 208, and the second resistive load 252 are variable.

10. The internal reflection cancelling full duplex node of claim 9,
wherein the splitter 202 is configured to receive a downstream signal 224 into the splitter input port 203, transmit a first portion of the downstream signal 224 out of the splitter common port 204, and transmit a second portion of the downstream signal 224 out of the splitter output port 205, wherein the first portion is greater than the second portion; and
wherein the splitter 202 is further configured to receive an upstream signal 226 into the splitter common port 204, transmit a first portion of the upstream signal 226 out of the splitter output port 205 and transmit a second portion of the upstream signal 226 out of the splitter input port 203, wherein the first portion is greater than the second portion.

11. The internal reflection cancelling full duplex node of claim 10,
wherein the common impedance matching network 220 comprises a first capacitor 244, a first inductor 242, and a second capacitor 246;
wherein the first capacitor 244 is coupled between a first end of the first inductor 242 and ground;
wherein the second capacitor 246 is coupled between a second end of the first inductor 242 and ground; and
wherein the first inductor 242, the first capacitor 244 and the second capacitor 246 are variable.

12. An internal reflection cancelling full duplex node comprising:
an output port 121;
a coupler 102 coupled to a downstream line, an upstream line, and a common line;
a power choke 110 coupled in parallel between the common line and ground;
a common impedance matching network 120 interposed in the common line between the power choke 110 and the output port 121; and
a tunable coupler impedance matching network 156 coupled to the coupler 102; wherein
the coupler 102 is a cross-connected transformer.
